(19) United States
(12) Patent Application Publication
(10) Pub. No.: US 2008/0136024 A1
(43) Pub. Date: Jun. 12, 2008

(54) SEMICONDUCTOR DEVICE

(75) Inventors: Yasuhiro NAKA, Ibaraki (JP); Hiroyuki Tenmei, Kanagawa (JP); Kunihiko NISHI, Tokyo (JP); Hiroaki IKEDA, Tokyo (JP); Masakazu ISHINO, Tokyo (JP)

Correspondence Address: SCULLY SCOTT MURPHY & PRESSER, PC, 400 GARDEN CITY PLAZA, SUITE 300, GARDEN CITY, NY, 11530, US

(73) Assignee: ELPIDA MEMORY, INC., Tokyo (JP)

(21) Appl. No.: 11/947,393

(22) Filed: Nov. 29, 2007

(30) Foreign Application Priority Data
Nov. 29, 2006 (JP) 2006-322221

(51) Int. Cl. H01L 23/48

(52) U.S. Cl. 257/737; 257/E23.01

(57) ABSTRACT

In a semiconductor device provided by preventing connection failure caused by misalignment of a semiconductor element having fine and narrow-pitched bumps, a guide for preventing the misalignment is formed by an insulating resin layer around a connection electrode. The insulating resin layer has a thickness defined in relation to an angle θ formed by a side wall of the opening and alignment accuracy δ for the bump. Specifically, the thickness of the insulating resin layer may be δ tan θ or more.

This application is based upon and claims the benefit of priority from Japanese patent application No. 2006-322221, filed on Nov. 29, 2006, the disclosure of which is incorporated herein in its entirety by reference.

### BACKGROUND OF THE INVENTION

1. Field of the Invention

The present invention relates to a semiconductor device which has a semiconductor element mounted on a packaging board through connection bumps.

2. Description of the Related Art

A flip-chip connection method has been used to connect a semiconductor element having connection bumps formed on a circuit face side to a packaging board, with the circuit surface side of the semiconductor element faced down towards the packaging board. It often happens that, after the connection, a resin called “under-fill” is inserted between the semiconductor element and the packaging board for ensuring reliability of the bump. The under-fill may be inserted after the connection or may be provided by applying a resin on the board surface prior to the connection and thereafter by thermally contact-bonding the semiconductor element onto the resin.

On implementing a semiconductor element onto a board, alignment of the semiconductor element is typically carried out by using a mechatronic control technology. A proposal for improving the alignment accuracy has been made, for example by Japanese Laid-Open Publication 1999-317425 (Patent Reference 1). This patent reference 1 describes a method of forming a barrier as a guide around each connection pad on a packaging board so as to locate each bump at predetermined positions (see, Patent Reference 1, claim 1 and FIG. 1).

In practice, however, when a bump diameter has a diameter smaller sonic control technology will inevitably cause a misalignment of up to 10% of the bump diameter to occur. This may adversely affect electrical resistance of the connection and reliability in strength of the connection. In view of the recent trend that the bump diameter is only a barrier serving as a guide is provided, will not be able to ensure sufficient alignment accuracy.

In addition, this kind of technique of using such guides has a problem that thermal expansion of a resin used for the guide brings about strain to the guide. A photosensitive resin of a high workability is employed for the guide. In general, this type of photosensitive resin has a high coefficient of thermal expansion. The thermal expansion of the photosensitive resin affects the reliability of the flip-chip connection against temperature variation during operation of the semiconductor device. It is known that a life time becomes short as the coefficient of thermal expansion of the under-fill becomes higher. This is described for example in Journal of Japan Institute of Electronics Packaging, vol. 8, No. 4 (2005), pp. 308-317 (Non-Patent Reference 1). Therefore, when employing under-fill, it is necessary to avoid the effects due to thermal expansion of the resin.

### SUMMARY OF THE INVENTION

In view of the technical background as described above, the present invention provides a technique capable of ensuring sufficient alignment accuracy even if a bump diam

The present invention provides a semiconductor device with high reliability by minimizing the effect of thermal expansion of the under-fill.

A basic configuration of the present invention is as described below. The present invention relates to a semiconductor device having, at least, a packaging board, a semiconductor element, and a bump electrode provided on the principal surface of a substrate of the semiconductor element. The bump electrode of the semiconductor element is electrically connected to an electrode provided on the packaging board, and a resin layer (so-called under-fill mentioned in the above) is provided in a gap between the semiconductor element and the packaging board. An insulating resin layer is provided around the electrode of the packaging board, and the insulating resin layer has an opening at a position corresponding to the position of the bump electrode. When the angle formed by the side wall defining the opening in the insulating resin layer with the up positional accuracy can be ensured even if degrees to enable the insulating resin layer to exhibit a sufficient effect as a guide for the bump electrode. Further, in order to all alignment accuracy, the ratio of the thickness of the insulating resin layer to the height of the bump is required to be ½ or more.

In view of another aspect of the present invention, it is desirable in order to obtain sufficient reliability of the semiconductor device, that the thickness of the resin layer provided in the gap between the semiconductor element and the packaging board satisfies the relation as described below, with the thermal expansion of the resin layer and the strain applied to the bump electrode. When the insulating resin layer having the opening has a coefficient of thermal _{G}, and the resin layer provided in the gap between the semiconductor element and the packaging board has a coefficient of thermal expansion of α_{U}, the ratio of the thickness of the insulating resin layer to the height of the bump should be (50−α_{U})/(α_{G}−α_{U}) or less. Therefore, it is practically required that the ratio of the thickness of the insulating resin layer to the height of the bump is equal to or more than ½ but equal to or less than ⅘.

Although the description above has been made in terms of an example in which the bump electrode is provided on the semiconductor element while the guide is provided on the packaging board, the present invention may be embodied by reversing these arrangements. Specifically, the bump electrode may be provided on the packaging board, while the guide may be provided on the semiconductor element. Further, the present invention is also applicable to a configuration in which a plurality of semiconductor elements are stacked on a single packaging board.

According to the present invention, it is made possible to effectively prevent the misalignment when connecting a semiconductor element to a packaging board by flip-chip connection in a manufacturing process of a semiconductor device.

According to another aspect of the present invention, sufficient reliability of the semiconductor device can be ensured by reducing the load applied to the connection of the semiconductor element due to temperature variation during the operation of the device.

### BRIEF DESCRIPTION OF THE DRAWINGS

FIG. 1 is a cross-sectional view showing the vicinity of a bump of a semiconductor device according to a first embodiment of the present invention;

FIG. 2 is a cross-sectional view showing the vicinity of a bump in the semiconductor device according to the first embodiment of the present invention, in which the bump is misaligned with an electrode;

FIG. 3 is a diagram illustrating an example of relation between plastic strain and a coefficient of thermal expansion of an insulating resin;

FIG. 4 is a cross-sectional view showing another example of a method to produce the configuration of the first embodiment of the present invention;

FIG. 5 a cross-sectional view showing the vicinity of a bump of a semiconductor device according to a second embodiment of the present invention;

FIGS. 6A to 6C are cross-sectional views for explaining a layered configuration of a semiconductor device according to a third embodiment of the present invention; and

FIG. 7 is a cross-sectional view showing a semiconductor device according to a fourth embodiment of the present invention.

### DETAILED DESCRIPTION OF THE INVENTION

The present invention will be described in detail, using a first embodiment thereof.

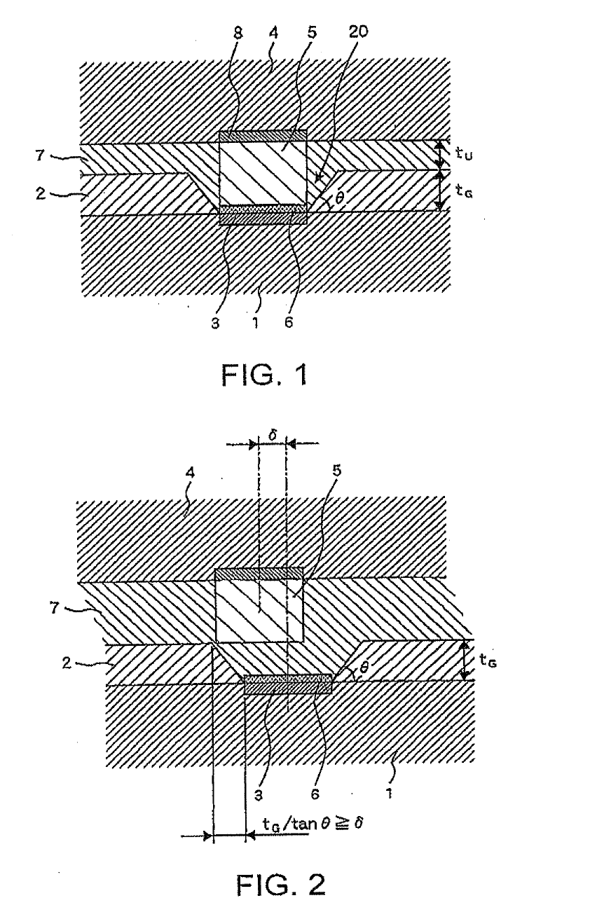

FIG. 1 is a cross-sectional view showing a basic configuration in the vicinity of a bump electrode of a semiconductor device. A resin layer 2 is formed on a principal surface of a packaging board 1 and serves as a guide for preventing misalignment. The packaging board, the resin layer for guide, a bump, and an under-fill may be formed by using materials conventionally used for these purposes. The resin layer 2 is usually formed of a photosensitive resin while the packaging board is usually formed of a resin or ceramic. An opening 20 is provided in the guide at a position corresponding to the position of a connection electrode 3 on the board 1. The opening 20 is usually formed by etching. The side wall defining the opening 20 in the resin layer 2 has a slope inclined at an angle θ to the principal surface of the board 1. This inclination angle θ must be set to a desired range, which will be described later. A semiconductor element 4 has a bump 5 which is fitted in this guide and which is electrically connected to the electrode 3 by means of a solder 6. The bump 5 is also connected to an electrode 8 of the semiconductor element 4. A film of Cu, Au or Ni may be plated on each surface of the electrodes 3 and 8 so as to improve a connection property with the bump 5. The bump 5 of the semiconductor element is made of Cu, Au or Ni and formed for example by plating. The bump may be, for example, a solder. The bump 5 generally has a diameter and a height both of which may be, for example, several tens of μm or less. The connection between the bump 5 and the electrode 3 of the packaging board 1 is performed by heating and imposing a load on the semiconductor element side. During the connection, a high frequency vibration may be simultaneously applied. A thin film of a solder 6 (for example, Sn or a Sn alloy) may be formed on the surface of the bump 5 for improving the connection property.

After the semiconductor element 4 is bonded or joined on the packaging board 1, an under-fill 7 is inserted between the semiconductor element 4 and the packaging board 1. The under-fill 7 is usually provided by using an anisotropic conductive film (ACF) or non-conductive film (NCF).

In FIG. 1, t_{G} denotes a thickness of the resin layer, namely, the guide layer 2, and t_{U} denotes a thickness of the under-fill 7. Although the description above has been made about an example of inserting the under-fill 7 after the joining between the semiconductor element 4 and packaging board 1, the under-fill 7 may be preliminarily applied on the packaging board 1 and then the semiconductor element 4 may be connected thereon.

Temporarily referring to FIG. 4, illustration is made about the above-mentioned method. In FIG. 4, a plurality of guide layers 2 are provided on the packaging board 1, and the electrodes 3 on the board side are arranged in the openings of the guide layers 2. The under-fill 7 is applied on the board 1 with openings formed at positions corresponding to the respective bumps 5. The semiconductor element 4 with the bumps 5 is pressure-bonded to the solder 7.

FIG. 2 is a cross-sectional view showing the vicinity of the bump electrode so as to describe misalignment between the bump 5 and the opening 20. The components shown in FIG. 2 are the same as those described with reference to FIG. 1. In the example shown in FIG. 2, the center of the bump 5 is offset or displaced from the central axis of the opening 20 by δ. As is understood from the example of FIG. 2, the thickness to of the guide layer 2 must be at least δ tan θ or more in order to allow a flip-chip connection apparatus to have an alignment error δ that might be at least 2 μm. When the photosensitive resin layer 2, namely, the guide layer is processed by etching, the angle θ formed in the opening 20 by the resin layer 2 is about an angle from 70 to 80 degrees. If the angle θ is too large or too small, the function as the guide will be impaired. Specifically, if the angle θ is too large, a sufficient alignment effect cannot be obtained. On the other hand, if the angle θ is too small, it will be substantially meaningless to provide the inclination of the angle θ itself. When an alignment error or allowance δ is surely maintained within a range between 2 and 3 μm, the thickness t_{G} should be 10 to 15 μm when the angle θ is 80 degrees. When the angle θ is 70 degrees, the thickness t_{G} should be about 5.5 to 8 μm. In practice, the angle itself possibly has a processing error of 2 to 3 degrees.

In this example, the bump has a diameter of several tens of μm, for example 20 to 30 μm. Therefore, the bump height H is also several tens of μm, for example 20 to 30 μm. When the angle θ is 80 degrees and the components have the dimensions as described above, the guide thickness to required to prevent the misalignment can be obtained by setting the same to at least ½ or more of the bump height H. When the angle θ is 70 degrees, the bump is preferably smaller, for example with a diameter of about 11 to 16 μm, in order to obtain a sufficient guiding effect.

In view of the second aspect of the present invention, it is necessary to consider about a relationship between the strain imposed onto the guide layer 2 and the thickness t_{G} of the guide layer 2. This is because the strain to the guide layer 2 is largely varied due to a coefficient of thermal expansion of the guide layer 2 in dependence upon the thickness t_{G} of the guide layer. Specifically, if the thickness of the resin layer 2 is too large, the strain to the guide caused by the thermal expansion becomes serious.

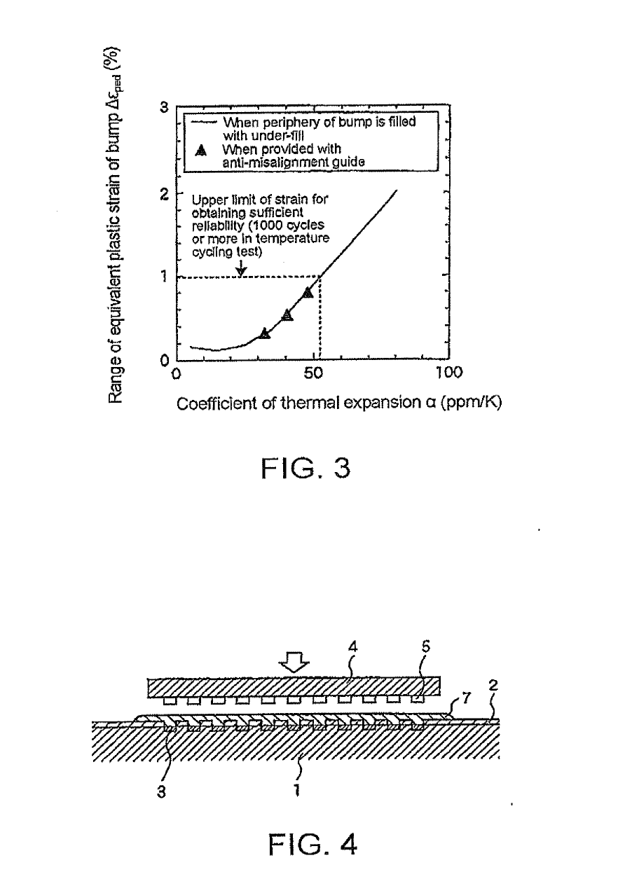

An elastoplastic analysis was conducted by using a finite element method to consider this problem FIG. 3 shows an analysis result obtained by using a typical bump formed of Cu (copper). The horizontal axis represents a coefficient of thermal expansion of the resin, while the vertical axis represents a range of plastic strain of the bump Δε_{ped} (%). The value of Δε_{ped} (%) was obtained here as an amount of equivalent plastic strain generated by the temperature change from 150° C. to −55° C. when a temperature cycling test was conducted in a temperature range of −55° C. to 150° C.

As a result, it was found that when a guide was provided for preventing the misalignment as in the present invention, the relationship between a coefficient α of thermal expansion and strain to the bump exhibits the same characteristics as those shown in FIG. 3 when the equivalent coefficient α of thermal expansion was defined as indicated by the expression (1) below. This representative result is shown as the plots of the solid triangles in FIG. 3.

The coefficient α of thermal expansion can be represented by the following expression (1).

α=(α_{G}t_{G}+α_{U}t_{U})/(t_{G}+t_{U}) (1)

where α_{G} denotes a coefficient of thermal expansion of the guide layer 2, α_{U} denotes a coefficient of thermal expansion of the under-fill 7, t_{G} denotes a thickness of the guide layer 2, and t_{U} denotes a thickness of the under-fill 7.

Herein, it has been confirmed that sufficient reliability is accomplished as long as the strain occurring in the bump is equal to 1% or less. Accordingly, by setting the relationship between the guide layer 2 and the under-fill 7 within the range enclosed by the broken lines in FIG. 3, the semiconductor device is enabled to have a service life of 1000 cycles or more in the temperature cycling test and hence to have sufficient reliability. Consequently, the following relation can be obtained based on the expression (1).

The expression (1) can be transformed as follows.

t_{G}/(t_{G}+t_{U})=(α−α_{U})/(α_{G}−α_{U}) (2)

Taking into consideration the range for ensuring the reliability shown in FIG. 3, the equivalent coefficient α of thermal expansion must be 50 ppm/K or less. Therefore, the reliability of the bump can be ensured if the ratio of the bump height (t_{G}+t_{U}) to the guide thickness (t_{G}) (t_{G}/(t_{G}+t_{U}) satisfies the following expression (3).

t_{G}/(t_{G}+t_{U})≦(50−α_{U})/(α_{G}−α_{U}) (3)

The photosensitive insulating resin used for the guide layer 2 typically has a coefficient of thermal expansion of about 55 ppm/K, while the under-fill has a coefficient of thermal expansion of about 30 ppm/K. Taking into consideration these conditions, it is extremely preferable that the ratio of the guide thickness to the bump height is ⅘ or less based on the expression (3).

A second embodiment of the present invention will be described in terms of an example in which the anti-misalignment guide layer 2 is provided on the semiconductor element side. It should be noted that the configuration, material, and fabricating method of the components in the second embodiment are the same as those in the first embodiment.

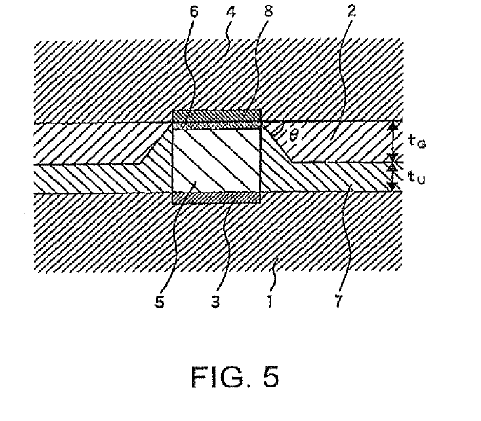

FIG. 5 is a cross-sectional view showing the vicinity of a bump according to the second embodiment. The same reference numerals are used for the same components as those of the embodiment described above. In this embodiment, the guide layer 2 for preventing misalignment is formed on the substrate side of the semiconductor element 4. In this case, the bump 5 is formed on the electrode 3 of the packaging board 1. The electrode 8 of the semiconductor element and the bump 5 are joined or bonded together in the same manner as the first embodiment described above. The side wall of the opening in the guide layer 2 is inclined at an angle θ to the principal surface of the semiconductor substrate. It should be noted that, in FIG. 5, the reference numeral 4 designates the semiconductor element including the semiconductor element substrate, without using a separate reference numeral for the semiconductor element substrate. Therefore, when explaining about the angle θ, the semiconductor element substrate is also treated as the component designated by the reference numeral 4 in FIG. 5. The same applies to the following description. When the alignment accuracy for connecting the semiconductor element to the bump is denoted by δ, the guide thickness should be δ tan θ or more as described above. Further, when taking into consideration the reliability of connection of the bump, it is obvious that the guide thickness should be set as defined by the expression (3). It is also obvious that the other conditions are also the same as described above. The change of the design of the semiconductor element itself is required in accordance with the change in the electrode arrangement from one surface to the other of the semiconductor substrate. It is obvious that this can be done by using a well-known technology related to a semiconductor device.

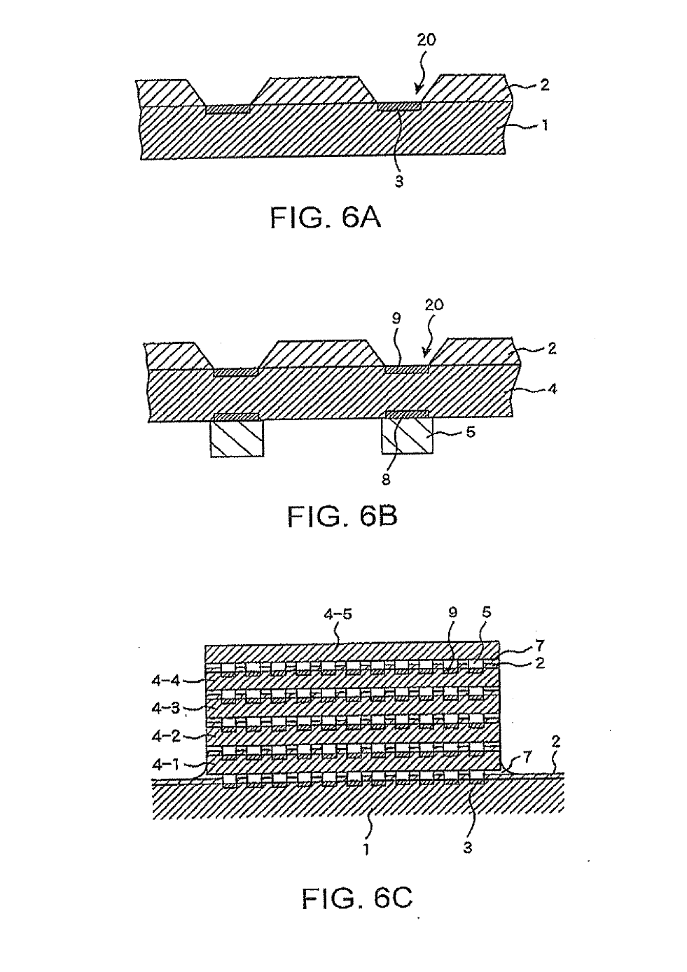

FIGS. 6A to 6C show cross-sectional views for describing a semiconductor device according to a third embodiment of the present invention in which a plurality of semiconductor elements 4 are stacked on the packaging board 1. FIG. 6C is a cross-sectional view of the completed semiconductor device. FIG. 6A is a cross-sectional view of the packaging board, and FIG. 6B is a cross-sectional view of the semiconductor element. According to this embodiment, the packaging board 1 and the semiconductor element 4 are configured as described below. An insulating resin layer for guides is formed as a guide layer 2 on the upper face of the packaging board 1 in the same manner as the embodiment shown in FIG. 1. Openings 20 for the guides are formed in the insulating resin layer at positions corresponding to the positions of lower-face electrodes of the semiconductor element and electrodes 3 are formed within the openings 20 (FIG. 6A). Likewise, each of the semiconductor elements 4-1, 4-2, 4-3, 4-4 and 4-5 (FIG. 6C) has an insulating resin layer 2 for providing guides on the surface thereof and the insulating resin layer 2 is provided with openings 20 serving as guides at the positions corresponding to those of upper-face electrodes of the semiconductor element. Bumps 5 are provided on the lower face of each semiconductor element (FIG. 6B). The bumps 5 are connected to the electrodes 9 provided on the upper face of the semiconductor element 4. Like the embodiments described above, the thickness of the guide layer should be δ tan θ or more in the relation to the angle of inclination θ of the opening of each guide 2 and the alignment accuracy 6 of the semiconductor element connection. It will be understood, based on the configuration of this embodiment, that no guide is required on the upper face of the uppermost semiconductor element 4-5.

Further, it is preferable, in consideration of the reliability of the bump connection, that the thickness of the insulating resin layer for providing the guides is set in the range represented by the expression (3) above.

It is also possible to reverse the components, or the bump and the guide, provided on the upper and lower faces of the semiconductor element and the upper face of the packaging board. In this event, bumps instead of the guides may be provided on the upper face of the packaging board. The design of each semiconductor element itself is required to be changed in accordance with the change in the electrode arrangement on the upper and lower faces of the semiconductor substrate. It is obvious that this can be done by using a well-known technology related to a semiconductor device. Unless otherwise noted, the configuration, material, and fabricating method of the components in the third embodiment are the same as those in the embodiments described above.

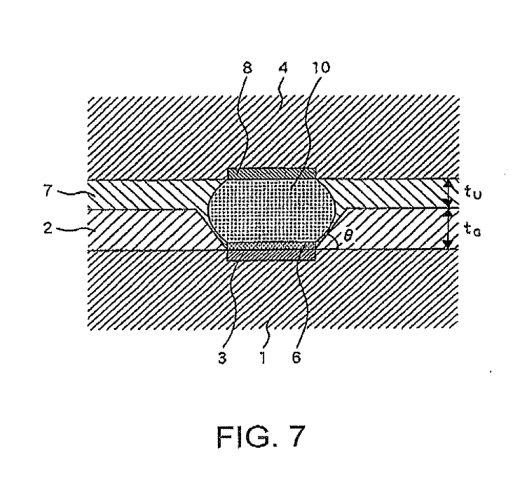

Description will be made of a fourth embodiment of the present invention in which a solder 10 is used as each bump for connection of the semiconductor element. FIG. 7 is a cross-sectional view showing the vicinity of a guide according to this fourth embodiment. The configuration is the same as that of FIG. 1 except that the solder 10 is used for the bump for connection between the packaging board and the semiconductor element. The solder may be formed by Sn (tin) or a Sn alloy. Like the embodiments described above, the thickness of the guide layer 2 should be δ tan θ or more in the relation to the angle of inclination θ of the opening of the guide layer 2 and the alignment accuracy 6 for the connection of the semiconductor element. Further, in consideration of the reliability of the bump connection, it is preferable to set the thickness of the guide layer 2 to the range represented by the expression (3) above. Obviously, the solder 10 according to this embodiment may also be employed in the second and third embodiments above.

The present invention has been described in detail. Main aspects of the invention will be defined and enumerated as follows.

(1) A semiconductor device having, at least, a packaging board, a semiconductor element, an electrode provided on the packaging board, and a bump electrode provided on a substrate of the semiconductor element, the bump electrode of the semiconductor element being electrically connected to the electrode of the packaging board, and a resin layer being provided in a gap between the semiconductor element and the packaging board, wherein:

an insulating resin layer is provided around the electrode of the packaging board, the insulating resin layer having an opening at a position corresponding to the position of the bump electrode; and

when the angle formed by the side wall of the opening in the insulating resin layer with the upper face of the packaging board is denoted by θ and the alignment accuracy for the bump is denoted by δ, the insulating resin layer has a thickness of δ tan θ or more.

(2) The semiconductor device according to the paragraph (1) above, wherein the angle θ is within a range from 70 to 80 degrees.

(3) The semiconductor device according to the paragraph (1) or (2) above, wherein when the insulating resin layer having the opening has a coefficient of thermal expansion of α_{G}, and the resin layer provided in the gap between the semiconductor element and the packaging board has a coefficient of thermal expansion of α_{U}, the ratio of the thickness of the insulating resin layer to the height of the bump is (50−α_{U})/(α_{G}−α_{U}) or less.

(4) The semiconductor device according to any one of the paragraphs (1) to (3) above, wherein the ratio of the thickness of the insulating resin layer to the height of the bump is ½ or more.

(5) The semiconductor device according to any one of the paragraphs (1) to (3) above, wherein the ratio of the thickness of the insulating resin layer to the height of the bump is equal to or more than ½ but equal to or less than ⅘.

(6) The semiconductor device according to any one of the paragraphs (1) to (5) above, wherein the bump has a diameter of 20 μm or less.

(7) A semiconductor device having, at least, a packaging board, a semiconductor element, a bump electrode provided on the packaging board, and an electrode provided on a substrate of the semiconductor element, the bump electrode of the packaging board being electrically connected to the electrode of the semiconductor element, and a resin layer being provided in a gap between the semiconductor element and the packaging board, wherein:

an insulating resin layer is provided around the electrode on the semiconductor element substrate, the insulating resin layer having an opening at a position corresponding to the position of the bump electrode; and

when the angle formed by the side wall of the opening in the insulating resin layer with the upper face of the semiconductor element substrate is denoted by θ and the alignment accuracy for the bump is denoted by δ, the insulating resin layer has a thickness of δ tan θ or more.

(8) The semiconductor device according to the paragraph (7) above, wherein the angle θ is within a range from 70 to 80 degrees.

(9) The semiconductor device according to the paragraph (7) or (8) above, wherein when the insulating resin layer having the opening has a coefficient of thermal expansion of α_{G}, and the resin layer provided in the gap between the semiconductor element and the packaging board has a coefficient of thermal expansion of au, the ratio of the thickness of the insulating resin layer to the height of the bump is (50−α_{U})/(α_{G}−α_{U}) or less.

(10) The semiconductor device according to any one of the paragraphs (7) to (9) above, wherein the ratio of the thickness of the insulating resin layer to the height of the bump is ½ or more.

(11) The semiconductor device according to any one of the paragraphs (7) to (9) above, wherein the ratio of the thickness of the insulating resin layer to the height of the bump is equal to or more than ½ but equal to or less than ⅘.

(12) The semiconductor device according to any one of the paragraphs (7) to (11) above, wherein the bump has a diameter of 20 μm or less.

(13) The semiconductor device according to any one of the paragraphs (1) to (6) above, wherein:

the semiconductor element (hereafter referred to as the first semiconductor element) has a connection electrode on the face of the first semiconductor element opposite from the face on which the bump electrode is provided;

an insulating resin layer is provided around the connection electrode, the insulating resin layer having an opening at a position corresponding to the position of the bump electrode;

when the angle formed by the side wall of the opening in the insulating resin layer with the upper face of the first semiconductor element substrate is denoted by θ and the alignment accuracy for the bump is denoted by δ, the insulating resin layer has a thickness of δ tan θ or more;

the semiconductor device further comprises at least one second semiconductor element having at least a bump electrode, the at least one second semiconductor element being stacked on the first semiconductor element with the connection electrode of the first semiconductor element being electrically connected to the bump electrode of the second semiconductor element; and

a resin layer being provided in a gap between the first semiconductor element and the second semiconductor element.

(14) The semiconductor device according to any one of the paragraphs (7) to (12) above, wherein:

the semiconductor element (hereafter referred to as the first semiconductor element) has a second bump electrode on the face of the first semiconductor element opposite from the face on which the electrode is provided;

the semiconductor device further comprises at least one second semiconductor element having at least a connection electrode;

a second insulating resin layer is provided around the connection electrode of the second semiconductor element, the second insulating resin layer having an opening at a position corresponding to the position of the bump electrode of the first semiconductor element;

when the angle formed by the side wall of the opening in the second insulating resin layer with the upper face of the second semiconductor element substrate is denoted by θ and the alignment accuracy for the second bump is denoted by δ, the second insulating resin layer has a thickness of δ tan θ or more;

the at least one second semiconductor element is stacked on the first semiconductor element with the bump electrode of the first semiconductor element being electrically connected with the connection electrode of the second semiconductor element; and

a second resin layer is provided in a gap between the first semiconductor element and the second semiconductor element.

(15) A semiconductor device having, at least, a packaging board, a semiconductor element, an electrode provided on either the packaging board or the semiconductor element, and a bump electrode provided on either the semiconductor element or the packaging board, the electrode provided on either the packaging board or the semiconductor element being electrically connected to the bump electrode provided on either the semiconductor element or the packaging board, and a resin layer being provided in a gap between the semiconductor element and the packaging board, wherein:

an insulating resin layer is provided around the electrode provided on either the packaging board or the semiconductor element, the insulating resin layer having an opening at a position corresponding to the position of the bump electrode; and,

when the insulating resin layer having the opening has a coefficient of thermal expansion of α_{G}, and the resin layer provided in the gap between the semiconductor element and the packaging board has a coefficient of thermal expansion of au, the ratio of the thickness of the insulating resin layer to the height of the bump is (50−α_{U})/(α_{G}−α_{U}) or less.

(16) A semiconductor device including a packaging board, a semiconductor element, an electrode provided on the packaging board, and a bump electrode provided on a substrate of the semiconductor element, the bump electrode of the semiconductor element being electrically connected to the electrode of the packaging board, wherein.

an insulating resin layer is provided around the electrode of the packaging board;

the insulating resin layer having an opening at a position corresponding to the position of the bump electrode and a thickness defined in relation to an angle θ formed by a side wall of the opening and alignment accuracy 6 for the bump. Thus, the present invention may not always be restricted only to a semiconductor device which has a resin layer provided in a gap between the semiconductor element and the packaging board.

What is claimed is:

1. A semiconductor device including a packaging board, a semiconductor element, an electrode provided on the packaging board, and a bump electrode provided on a substrate of the semiconductor element, the bump electrode of the semiconductor element being electrically connected to the electrode of the packaging board, wherein:
an insulating resin layer is provided around the electrode of the packaging board, the insulating resin layer having an opening at a position corresponding to the position of the bump electrode; and
when the angle formed by the side wall of the opening in the insulating resin layer with the upper face of the packaging board is denoted by δ and the alignment accuracy for the bump is denoted by δ, the insulating resin layer has a thickness of δ tan θ or more.

2. The semiconductor device according to claim 1, wherein the angle θ is within a range from 70 to 80 degrees.

3. The semiconductor device according to claim 2, wherein when the insulating resin layer having the opening has a coefficient of thermal expansion of α_{G}, and a resin layer provided in a gap between the semiconductor element and the packaging board has a coefficient of thermal expansion of α_{U}, the ratio of the thickness of the insulating resin layer to the height of the bump is (50−α_{U})/(α_{G}−α_{U}) or less.

4. The semiconductor device according to claim 2, wherein the ratio of the thickness of the insulating resin layer to the height of the bump is ½ or more.

5. The semiconductor device according to claim 2, wherein the ratio of the thickness of the insulating resin layer to the height of the bump is equal to or more than ½ but equal to or less than ⅘.

6. The semiconductor device according to claim 2, wherein the bump has a diameter of 20 μm or less.

7. A semiconductor device having, at least, a packaging board, a semiconductor element, a bump electrode provided on the packaging board, and an electrode provided on a substrate of the semiconductor element, the bump electrode of the packaging board being electrically connected to the electrode of the semiconductor element, and a resin layer being provided in a gap between the semiconductor element and the packaging board, wherein:
an insulating resin layer is provided around the electrode on the semiconductor element substrate, the insulating resin layer having an opening at a position corresponding to the position of the bump electrode; and
when the angle formed by the side wall of the opening in the insulating resin layer with the upper face of the semiconductor element substrate is denoted by θ and the alignment accuracy for the bump is denoted by δ, the insulating resin layer has a thickness of δ tan θ or more.

8. The semiconductor device according to claim 7, wherein the angle θ is within a range from 70 to 80 degrees.

9. The semiconductor device according to claim 8, wherein when the insulating resin layer having the opening has a coefficient of thermal expansion of α_{G}, and the resin layer provided in the gap between the semiconductor element and the packaging board has a coefficient of thermal expansion of au, the ratio of the thickness of the insulating resin layer to the height of the bump is (50−α_{U})/(α_{G}−α_{U}) or less.

10. The semiconductor device according to claim 8, wherein the ratio of the thickness of the insulating resin layer to the height of the bump is ½ or more.

11. The semiconductor device according to claim 8, wherein the ratio of the thickness of the insulating resin layer to the height of the bump is equal to or more than ½ but equal to or less than ⅘.

12. The semiconductor device according to claim 8, wherein the bump has a diameter of 20 μm or less.

13. The semiconductor device according to claim 1, wherein:
the semiconductor element (hereafter referred to as the first semiconductor element) has a connection electrode on the face of the first semiconductor element opposite from the face on which the bump electrode is provided;
an insulating resin layer is provided around the connection electrode, the insulating resin layer having an opening at a position corresponding to the position of the bump electrode;
when the angle formed by the side wall of the opening in the insulating resin layer with the upper face of the first semiconductor element substrate is denoted by θ and the alignment accuracy for the bump is denoted by δ, the insulating resin layer has a thickness of δ tan θ or more;
the semiconductor device further comprises at least one second semiconductor element having at least a bump electrode, the at least one second semiconductor element being stacked on the first semiconductor element with the connection electrode of the first semiconductor element being electrically connected to the bump electrode of the second semiconductor element; and
a resin layer being provided in a gap between the first semiconductor element and the second semiconductor element.

14. The semiconductor device according to claim 7, wherein:
the semiconductor element (hereafter referred to as the first semiconductor element) has a second bump electrode on the face of the first semiconductor element opposite from the face on which the electrode is provided;
the semiconductor device further comprises at least one second semiconductor element having at least a connection electrode;
a second insulating resin layer is provided around the connection electrode of the second semiconductor element, the second insulating resin layer having an opening at a position corresponding to the position of the bump electrode of the first semiconductor element;
when the angle formed by the side wall of the opening in the second insulating resin layer with the upper face of the second semiconductor element substrate is denoted by θ and the alignment accuracy for the second bump is denoted by δ, the second insulating resin layer has a thickness of δ tan θ or more;
the at least one second semiconductor element is stacked on the first semiconductor element with the bump electrode of the first semiconductor element being electrically connected with the connection electrode of the second semiconductor element; and
a second resin layer is provided in a gap between the first semiconductor element and the second semiconductor element.

15. A semiconductor device having, at least, a packaging board, a semiconductor element, an electrode provided on either the packaging board or the semiconductor element, and a bump electrode provided on either the semiconductor element or the packaging board, the electrode provided on either the packaging board or the semiconductor element being electrically connected to the bump electrode provided on either the semiconductor element or the packaging board, and a resin layer being provided in a gap between the semiconductor element and the packaging board, wherein:
an insulating resin layer is provided around the electrode provided on either the packaging board or the semiconductor element, the insulating resin layer having an opening at a position corresponding to the position of the bump electrode; and
when the insulating resin layer having the opening has a coefficient of thermal expansion of α_{G}, and the resin layer provided in the gap between the semiconductor element and the packaging board has a coefficient of thermal expansion of au, the ratio of the thickness of the insulating resin layer to the height of the bump is (50−α_{U})/(α_{G}−α_{U}) or less.

16. A semiconductor device including a packaging board, a semiconductor element, an electrode provided on the packaging board, and a bump electrode provided on a substrate of the semiconductor element, the bump electrode of the semiconductor element being electrically connected to the electrode of the packaging board, wherein:
an insulating resin layer is provided around the electrode of the packaging board;
the insulating resin layer having an opening at a position corresponding to the position of the bump electrode and a thickness defined in relation to an angle θ formed by a side wall of the opening and alignment accuracy δ for the bump.
